(19) United States
(12) Patent Application Publication
(10) Pub. No.: US 2009/0174072 A1
(43) Pub. Date: Jul. 9, 2009

(54) SEMICONDUCTOR SYSTEM HAVING BGA PACKAGE WITH RADIALLY BALL-DEPOPULATED SUBSTRATE ZONES AND BOARD WITH RADIAL VIA ZONES

(75) Inventor: Keven D. Coates, Cypress, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/056,939

(22) Filed: Mar. 27, 2008

Related U.S. Application Data
(60) Provisional application No. 61/019,056, filed on Jan. 4, 2008.

(51) Int. Cl. H01L 23/488; H05K 1/00; H01L 21/60

(52) U.S. Cl. 257/738; 174/262; 438/106; 257/E23.023; 257/E21.511

(57) ABSTRACT

A printed circuit board has contact lands (710) forms an array with depopulated elongated zones (820), which are radially oriented from the board center towards the board periphery. Conductive vias (803) are then clustered into these zones, the radial via channels. The radial orientation of via channels provides space needed for grouping, at the level of the internal metal layers, parallel traces (1101). Thus, the number of metal layers needed for the traces can be reduced. The device to be assembled on the board exhibits elongated radial zones free of contact pads matching the land-free zones (820) of the board.

### FIELD OF THE INVENTION

The present invention is related in general to the field of semiconductor devices and processes, and more specifically to structure, layout, and processes of ball grid array packages, and structure and layout of boards used in systems for assembling the packages.

### DESCRIPTION OF RELATED ART

Among the driving forces of the semiconductor markets are the long-term trend to increase functional complexity of semiconductor products, and to decrease the cost per functional unit. These driving forces affect the semiconductor devices including the packaged semiconductor chips, as well as the semiconductor systems including devices assembled on boards.

For the packages of semiconductor chips, the increasing product complexity typically translates into larger numbers of required input/output (I/O) terminals for signals and power, while the cost pressure calls against increase in package size. As an example, the popular ball grid array (BGA) package responded to these contradictory requirements by increasing the number of balls while reducing the ball size and the pitch between balls.

To install such a high I/O BGA package on a printed circuit boards (PCBs), there must be correspondingly high number of contact pads and conductive traces to connect the I/O terminals and the rest of the system on the board and the world beyond. Two approaches are available today for constructing a PCB for a small sized BGA package of large I/O count. One approach is to reduce the pitch of the conductive traces, that is, to decrease the width of the traces and the space between the traces so more traces can be crowded into the small area. The second approach is to increase the number of layers in the PCB and to use vertical through via holes to channel the signals from the BGA package deep into the lower layers.

### SUMMARY OF THE INVENTION

Applicant discovered an alternative and new method described herein with which to lay out the contact terminals in the BGA package and the corresponding contact pads (lands) on the PCB. With this method, the manufacture cost of a high I/O count, small footprint BGA/PCB system can be drastically reduced.

In one aspect of this invention, a number of areas of selected sites in the ball grid array are reassigned so instead of placing contact terminals and lands, these areas are used to cluster through-hole vias. In some embodiments, these areas take on the shape of elongated zones. In this paper, these zones are defined as via channels. Via channels that radiate outwardly from the center of the grid array area in which the BGA is placed on the PCB are termed radial via channels.

The radial orientation of via channels provides extra spaces to accommodate routing traces on the metal layers below the surface of the PCB, which otherwise would require additional layers of metal.

In the following table, three PCB layout examples are listed. The first layout is based on the rules that are currently used in the industry. Printed circuit boards that are laid out with these rules are routinely manufactured with satisfactory yield and at reasonable cost. The second layout is based on a set of more stringent rules which the industry will be forced to go to in order to accommodate the shrinking of I/O pitch in future devices. Because the rules are tighter in the second layout than what are practiced in the industry today, the learning curve will inevitably mean higher yield loss and that translates to higher cost.

The third layout is based on an embodiment of this invention. It is clear by comparison that the layout according to certain aspects of the invention, which uses the matured and more forgiving design rules, can accommodate more I/Os at a smaller pitch and with two fewer metal layers in the PCB construction—a huge cost reduction.

| | | | Alternative to | | Embodiment 1 | |
|---|---|---|---|---|---|---|
| | Current Art | | Invent | | of Invention | |
| I/O Pitch | 0.8 | mm | 0.65 | mm | 0.65 | mm |
| Minimum Trace Width | 125 | μm | 100 | μm | 125 | μm |
| Minimum Space | 125 | μm | 100 | μm | 125 | μm |
| Via Ring Diameter | 450 | μm | 350 | μm | 450 | μm |
| Package Size | 17 × 17 | mm² | 14 × 14 | mm² | 16 × 16 | mm² |

| | | | |
|---|---|---|---|
| Number of I/Os | 400 | 400 | 424 |
| Number of PCB | 6 | 6 | 4 |
| Layers | | | |

From this table, one can clearly see that as the I/O pitch is reduced from 0.8 mm to 0.65 mm in order to reduce the package footprint, the second layout has to reduce the pitch of the trace/space from 125 by 125 μm to 100 by 100 μm, which means the conductance per unit length of the traces will be raised by 20 percent. And the diameter of via rings, which is occupied by a through-hole via and its ancillary ring, is reduced from 450 μm to 400 μm. The reduction in trace pitch and the via ring area greatly increase the manufacture difficulty and thus lower manufacturing yield and this leads to higher manufacturing cost.

Layout number three, which embodies certain aspects of this invention, is also laid out for to accept a BGA with I/O pitch of 0.65 mm. Contrarily to the second lay-out above, the width of the conductive traces and the space between traces remain at 125 μm, which means the conductance is not reduced. The annular via rings remain at 450 μm wide, which makes manufacturing easy. Even with this matured design rules and its associated high manufacturing yield, this lay-out actually can accommodate 424 I/O's—more than 5% increase over what can be achieved with the more difficult alternative approach. And it requires two fewer metal layers for the traces.

Furthermore, the methodology of this invention is scalable. In other words, the method is perfectly applicable to future systems as the layout rules for BGA/PCB inevitably continue the trend of continuous miniaturization.

The technical advances represented by this and other embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 shows a schematic cross section of an electronic system including a ball grid array device connected to a multi-level printed circuit board by metallic bumps.

FIG. 2 is a top view of a portion of a conventional printed circuit board with metallic lands, traces, and vias.

FIG. 3 is an X-ray view of the surface and the first internal metal layer of a conventional printed circuit board with metallic lands, traces, and vias.

FIG. 4 is an X-ray view of the surface and the second internal metal layer of a conventional printed circuit board with metallic lands, traces, and vias.

FIG. 5 is an X-ray view of the surface and the third internal metal layer of a conventional printed circuit board with metallic lands, traces, and vias.

FIG. 6 shows a bottom view of a ball grid array package having contact pads in a regularly pitched array including elongated radial zones free of pads.

FIG. 7 is a top view of a portion of a printed circuit board depicting metallic lands in a regularly pitched array including elongated radial zones free of lands matching the pad-free zones of the ball grid array package in FIG. 6.

FIG. 8 is a top view of a portion of a printed circuit board depicting conductive vias clustered in the land-free zones shown in FIG. 7.

FIG. 9 illustrates a top view of a portion of a printed circuit board combining the regularly pitched land array with elongated radial zones free of lands having the conductive vias clustered in these land-free zones.

FIG. 10 shows a view of the first internal metal layer of the printed circuit board, depicting selectively the conductive vias to the board surface. The vias are clustered in radial zones forming vias channels. The arrows indicate the spaces between via channels available for positioning traces from central to peripheral board areas.

FIG. 11 is an X-ray view of the first internal metal layer of a portion of a printed circuit board, depicting the conductive vias and traces from the vias to the board periphery; the traces are positioned in the spaces between via channels. The board lands on the surface are also shown.

FIG. 12 is a view of the surface of a portion of a printed circuit board, showing the traces from the land lines and rows near the periphery, as well as traces from the lands to the vias clustered in radial zones.

### DETAILED DESCRIPTION OF THE PREFERRED EMBODIMENTS

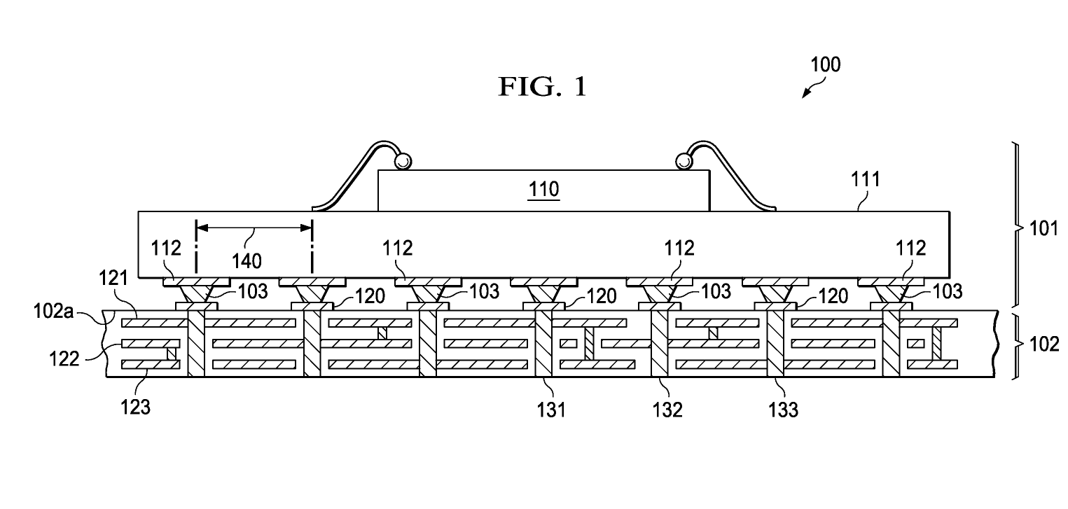

FIG. 1 illustrates an electronic system generally designates 100, which includes a semiconductor Ball Grid Array (BGA) device 101 connected to a printed circuit board (PCB, often simply referred to as the “board”) 102 by metal bodies 103 such as gold studs or solder balls. Device 101 includes a semiconductor chip 110 assembled on a substrate 111, which has metallic contact pads 112 for attaching the metal bodies 103. Alternatively, the contact pads 112 have a configuration for pressure contacts to external parts, or any other provision to enable electrical connection to external parts. As FIG. 1 indicates, pads 112 are preferably arranged in a regularly pitched array; the pitch is designated 140.

Board 102 is made of insulating material with a surface 102a. On surface 102a are metallic lands 120, which match the distribution of pads 112; in FIG. 1, lands 120 have the same regular pitch 140 as the pads 112. In FIG. 1, lands 122 are suitable for connections to metal bodies 103, such as gold or solder; alternatively, they could be prepared for pressure contacts. In addition, surface 102a has metallic traces.

Internal to board 102 are means for electrically conductive horizontal and vertical connections. In FIG. 1, the horizontal connections are enabled by traces 121, patterned from a first internal metal layer, by traces 122 patterned from a second metal layer, and by traces 123 patterned from a third metal layer. Additional layers may be added as the number of I/Os increases. However, each additional metal layer adds significantly to the cost of the board.

The vertical connections are enabled by metal-filled vias extending from the lands through the thickness of the board, with contacts to certain traces. In FIG. 1, some lands 120 are connected to first-level internal traces 121 by vias 131; other lands are connected to second-layer traces 122 by vias 132; and yet other lands are connected to third-level traces 123 by vias 133.

To properly place the traces on the various layers of a PCB so they can transmit the electrical signals from the terminal contact pads of the BGA to across the border of the array on the PCB to the external world is a challenge, especially if the board is laid out with conventional methodology. This is explained below.

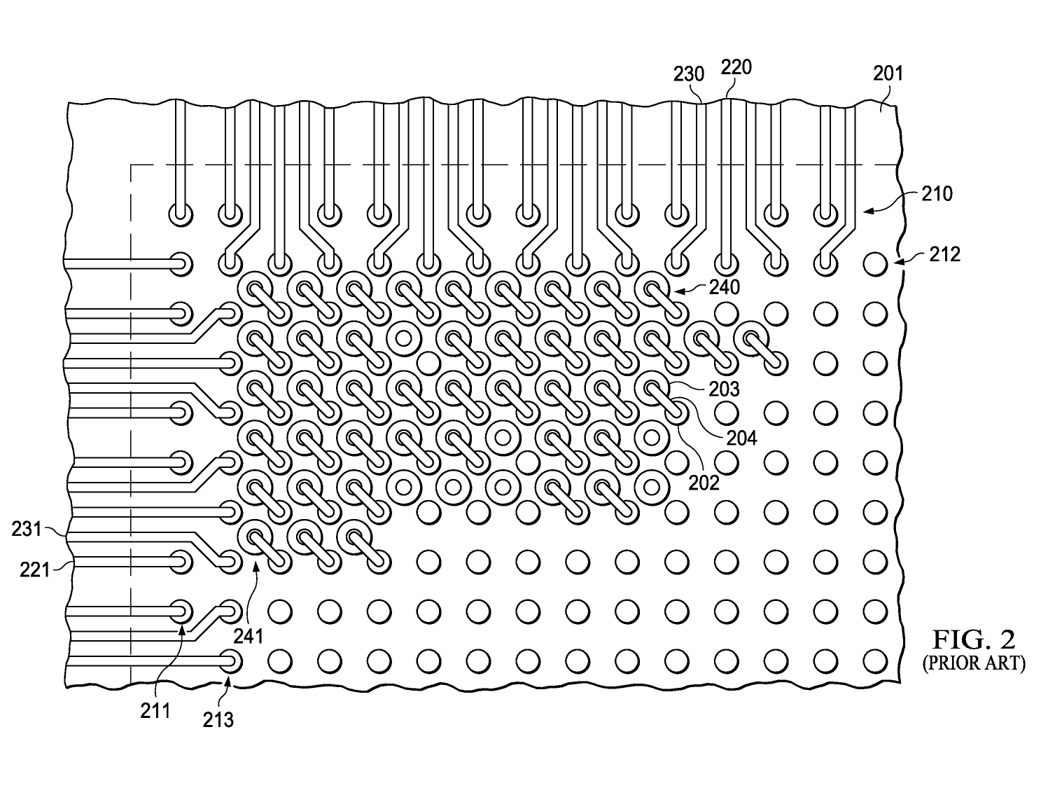

FIG. 2 illustrates the top surface of a quadrant of a conventional PCB 201. The metallic lands 202 on the surface are located on sites of a regularly pitched land-array. In this array, the horizontal lines are designated 210, and the vertical rows are designated 211. Vias 203 are interstitially placed between lands. The routing traces on the board surface include traces 220 extending from the lands in the first line 210 (counted from the periphery inward), and traces 221 extending from the lands in the first row 211 (counted from the periphery inward). Further, traces 230 extend from the lands in the second line 212, and traces 231 extend from the lands in the second row 213.

Traces 220 and 230, as well as traces 221 and 231, show parallel routing wherever possible. The pitch between parallel traces 220 and 230 and between parallel traces 221 and 231 has a big impact on the manufacturing cost of the board. For example, based on conventional laid out method, a land pitch of 0.65 mm requires 100 μm traces, which is more expensive than a board for land pitch of 0.80 mm pitch, which requires 125 μm traces. The size of the vias is also a significant cost factor for the boards; for example, 350 μm diameter vias are 10 to 15% more expensive than 450 μm diameter vias. This is because tighter rules require more costly manufacturing equipment and possible reduced manufacturing yield.

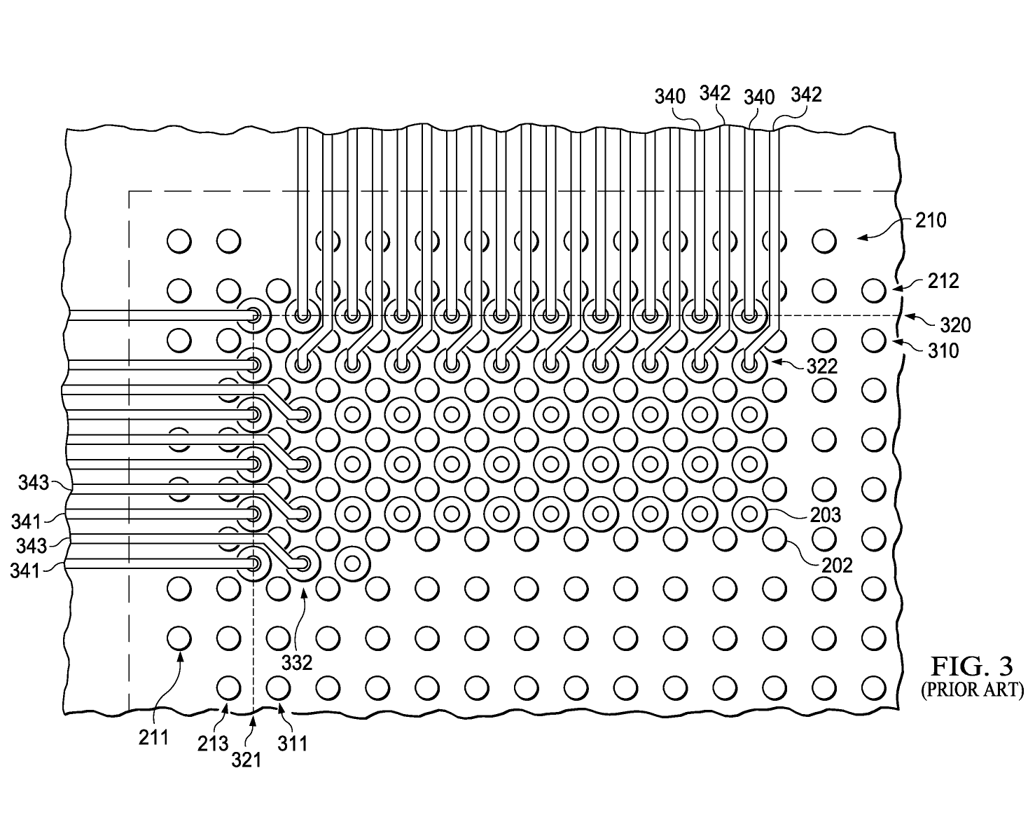

FIG. 3 shows a partial-X-ray figure of the same board quadrant as FIG. 2 yet at the first internal board metal layer. The locations of lands 202 and vias 203 of FIG. 2 are repeated and combined with the metal traces formed from the first internal metal layer. Today's matured routing rules require a minimum distance of 125 μm between lands and traces, and a minimum distance of 125 μm between via and adjacent land. These rules do not offer enough space for the traces connected to the lands of the third line 310 (and the third row 311) to exit the periphery of the array on the same metal layer as the first two lines 210 and 212 (and rows 211 and 213). Consequently, lands of the third line 310 (and row 311) have to use conductive vias to reach the next metal layer of the PCB.

On a conventionally laid out PCB, a line of vias 320 is placed between the second line 212 and third line 310 of lands, and a row of vias 321 is placed between the second and third row of lands, as marked by dotted line in FIG. 3. The traces connected to the vias in line 320 are designated 340; the traces are substantially parallel. The traces connected to the vias in row 321 are designated 341; the traces are substantially parallel.

A comparison of FIG. 3 with FIG. 2 shows that the location and the diameter of the vias determines the density of the parallel traces. In the example of FIG. 3, the trace density is 20 traces in 7.7 mm.

The effect of this conventional methodology of placing vias along lines, evenly distributed, is depicted in FIG. 3. The vias in line 320 and in row 321 act like a roadblock or dam, which stops the traces from vias closer to the center of the array from reaching the edges. In FIG. 3, there is just enough space for the traces 342 exiting from the vias in line 322 connected to the fourth line of lands to squeeze between the vias in lines 320, and there is just enough space for the traces 343 exiting from the next row 332 of vias to squeeze between the vias in row 321. However, no traces from vias in more remote lines and rows (connected to lands in lines and rows five, six and higher from the periphery) can reach the edges. Consequently, for every other line and row of vias, an additional layer of trace metal has to be provided in the board in order to serve lines and rows of the lands closer to the center—an expensive methodology for devices with high I/O count.

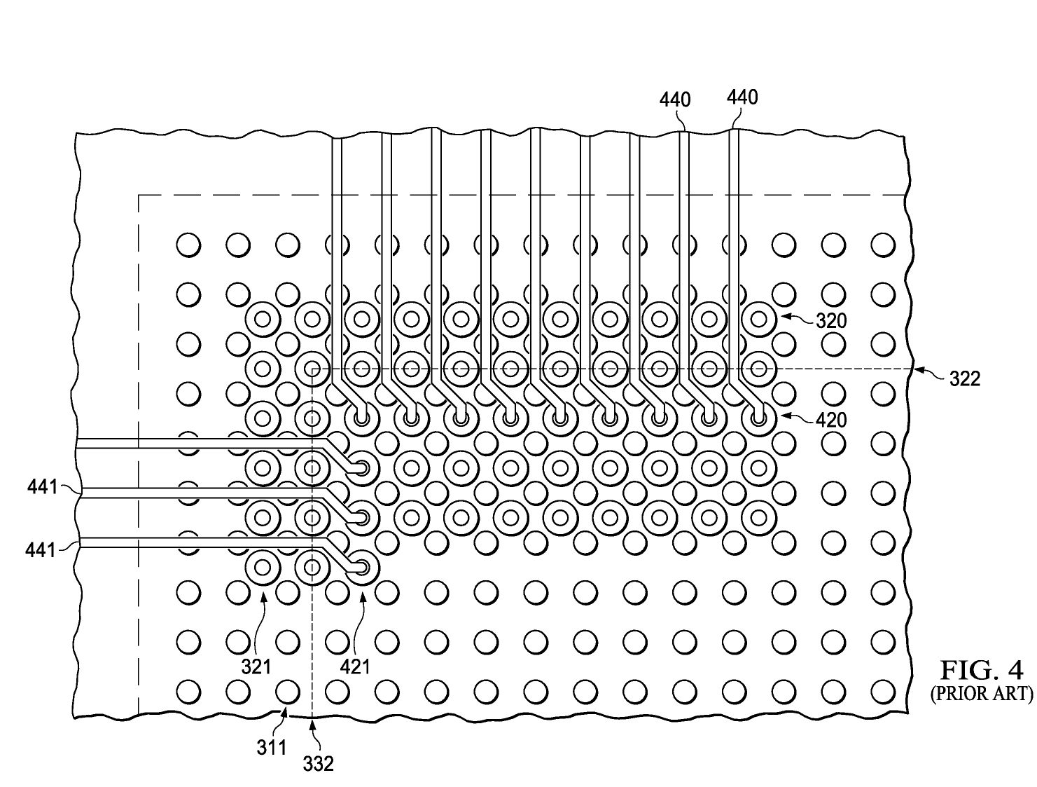

FIG. 4 shows the same board portion as FIG. 3 yet at the second internal board metal layer. FIG. 4 illustrates the effect of placing vias evenly distributed along line 322 and row 332, highlighted by dotted line; in addition, the previous line 320 and row 321 are shown. The effect of the vias in line 322 and row 332 is again like a dam: impeding the layout of traces 440 from the vias in line 420 and traces 441 from the vias in row 421.

A comparison of FIG. 4 with FIG. 3 shows that the density of the parallel traces is considerably reduced. In the example of FIG. 4, the trace density is only 20 traces in 16 mm. The reduction in trace density has to be compensated by increasing the number of board metal layers—an expensive penalty.

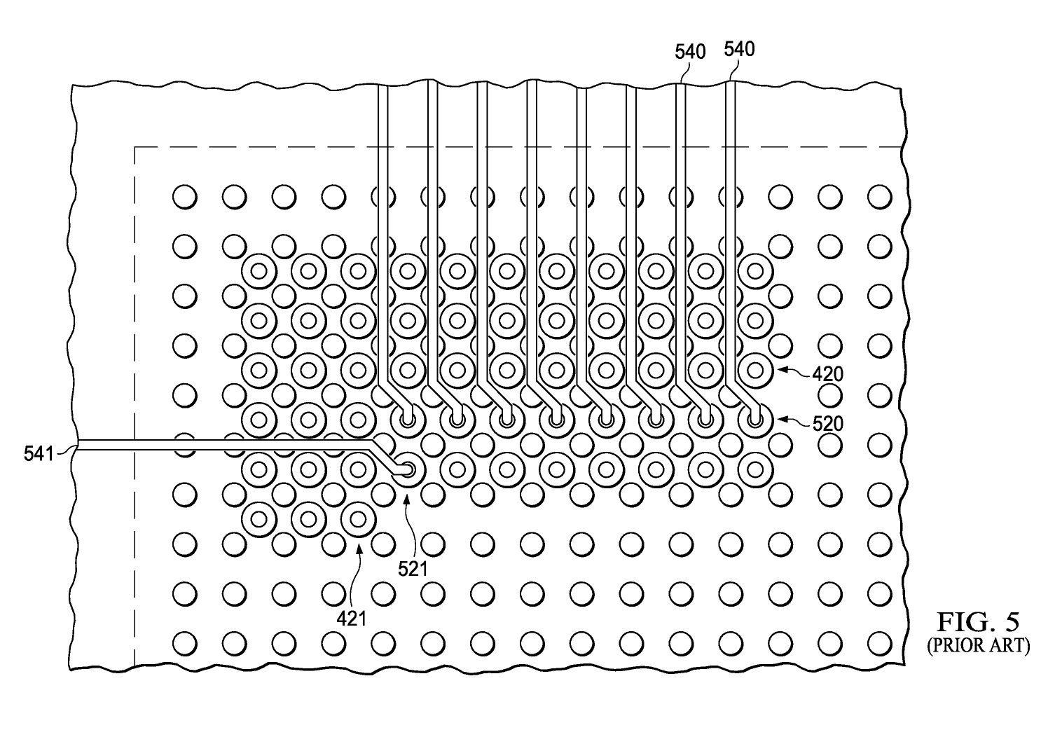

FIG. 5 depicts the same board portion as FIG. 4 yet at the third internal board metal layer. FIG. 5 repeats the methodology of placing vias evenly distributed along lines and rows; in addition, FIG. 5 shows the previous line 420 and row 421. The effect of the linear placing of the vias is again like a dam by impeding the layout of traces 540 from the vias in line 520 and traces 541 from the vias in row 521.

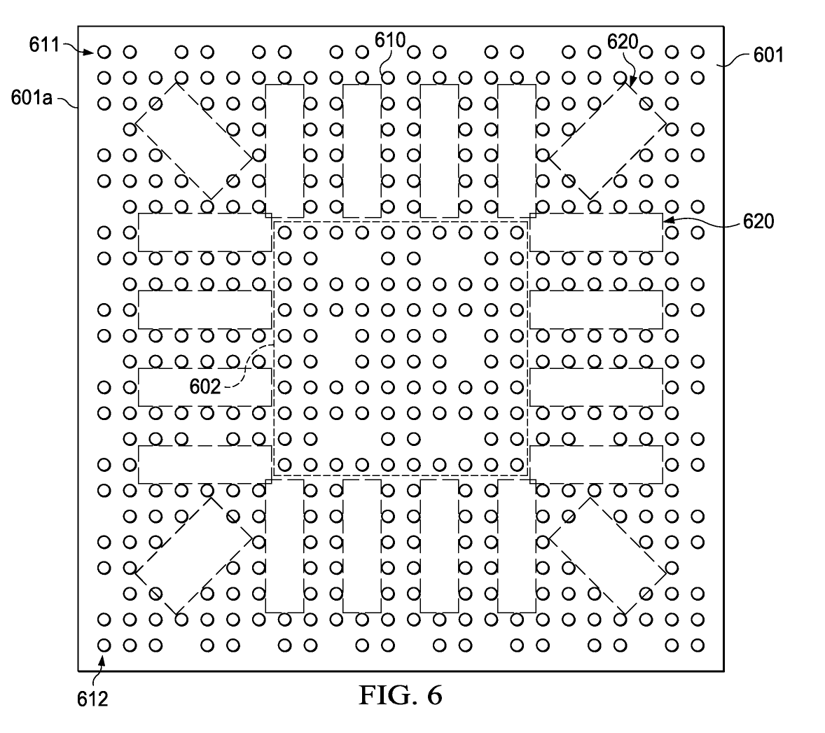

FIG. 6 depicts an embodiment of the invention. FIG. 6 shows the bottom view of an electronic package, depicting the bottom surface of substrate 601 with metallic contact pads 610. The package may belong to a wide group of electronic devices; a preferred example is a ball grid array (BGA) device, which has a semiconductor chip assembled on the substrate (indicated by dotted lines 602 in FIG. 6). In the embodiment of FIG. 6, the substrate has rectangular sides 601a. The pads 610 populate selected sites of a regularly pitched site-array. In the embodiment of FIG. 6, the array is aligned in lines 611 and rows 612 parallel to the rectangular substrate sides.

As FIG. 6 shows, the array on the bottom surface of the substrate has sites without contact pads. The pad-free sites form elongated zones 620 surrounded by contact pads. Zones 620 are located in the peripheral array areas surrounding the substrate center. Zones 620 have an orientation so that they are directed from the center of the substrate outwardly, radially to the substrate sides.

The metallic pads 610 have a metallurgical surface so that metal bumps (made of gold, solder, or a suitable alloy) for connection to external parts can be attached. Alternatively, the pad surfaces are prepared so that pressure contacts to external parts can be accomplished.

The packaged electronic device is to be assembled on a printed circuit board (PCB) made of an insulating board material such as FR-4 strengthened by glass fibers. The surface of the board has metallic lands suitable for interconnection to the bumps on the contact pads of the device package; alternatively, the lands may have a metallurgical preparation for pressure contacts. Since the device has its contact pads in a regularly pitched array including elongated radial zones free of pads, as illustrated in FIG. 6, the metallic lands on the surface of the PCB match the pad distribution.

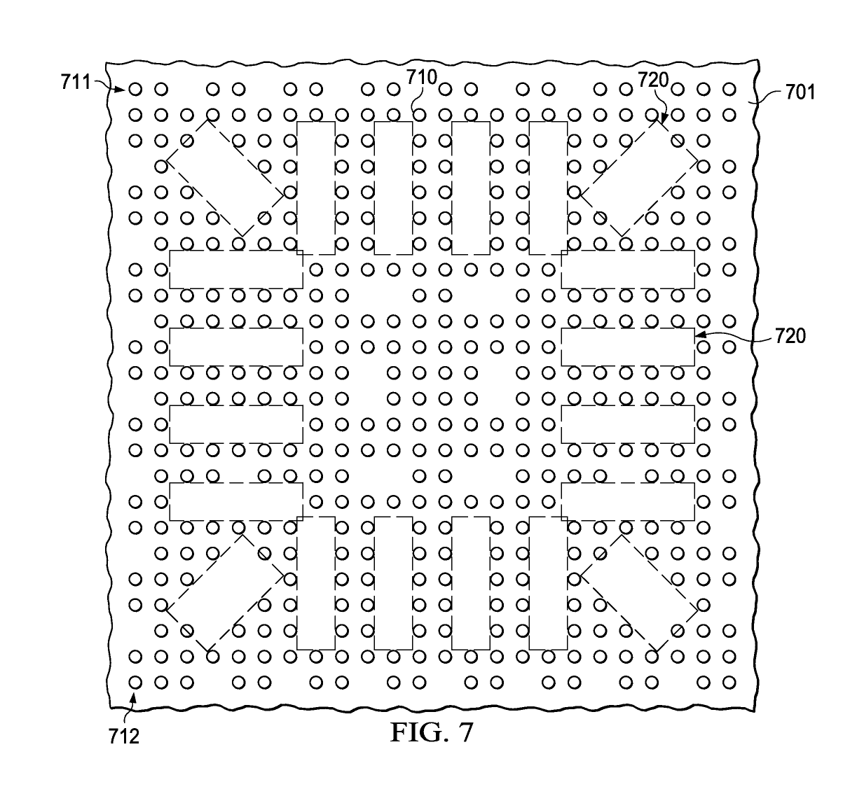

FIG. 7 represents the top view of the board; 710 are the metallic lands on the board surface 701. The lands 710 populate selected sites of a regularly pitched site-array, matching the contact pads of the device-to-be-assembled. In the embodiment of FIG. 7, the array is aligned in lines 711 and rows 712 parallel to the rectangular substrate edges of the device-to-be-assembled. The lands in this example have a diameter of 300 μm.

As FIG. 7 shows, the array on the top board surface further includes sites without lands. The aggregate of land-free sites form elongated zones 720 surrounded by lands 710. Zones 720 are located in the peripheral array areas surrounding the array center. Zones 720 have an orientation so that they are directed from the center of the array outwardly, radially to the substrate sides of the device-to-be-assembled.

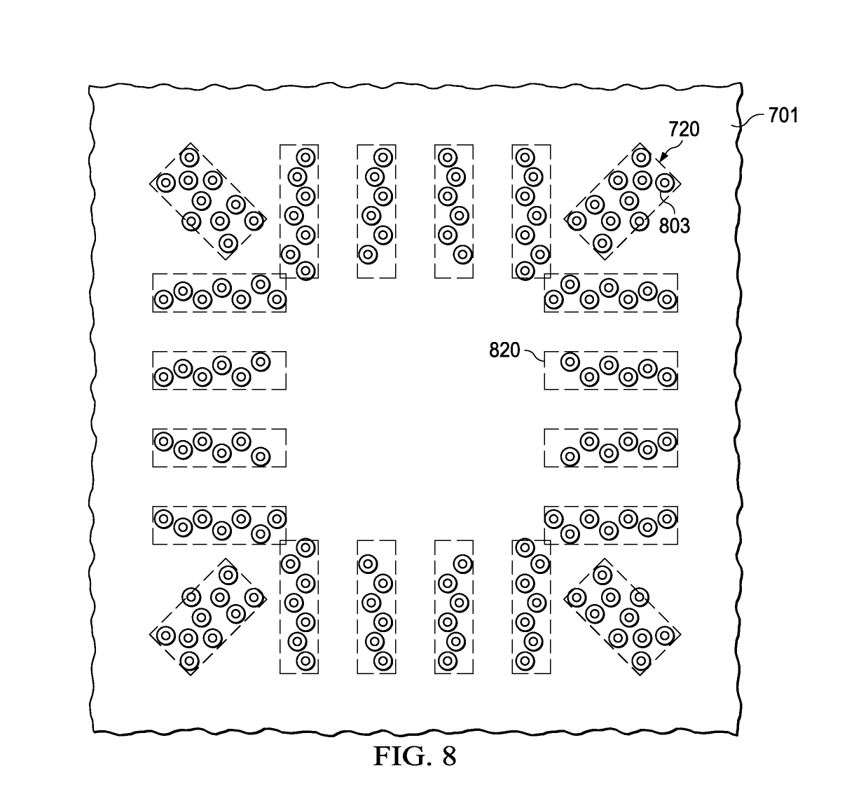

It is in the zones 720 that the conductive vias are clustered, which extend from the board surface 701 through the thickness of the board and connect to the interior metallization layer. FIG. 8 illustrates the vias 803 clustered in the zones 720 free of lands, as they appear in the top view of the board surface. In this paper, a group of vias clustered in a zone is referred to as a “via channel”, indicated by dashed outlines 820 in FIG. 8. Considering further the orientation of the zone in the direction from the PCB center to the PCB periphery, the cluster of vias is referred to as a “radial via channel”.

As FIG. 8 shows, the area made available for a radial via channel is large enough to allow the vias in this zone to have large diameter allowed by the distance rules to the adjacent PCB lands.

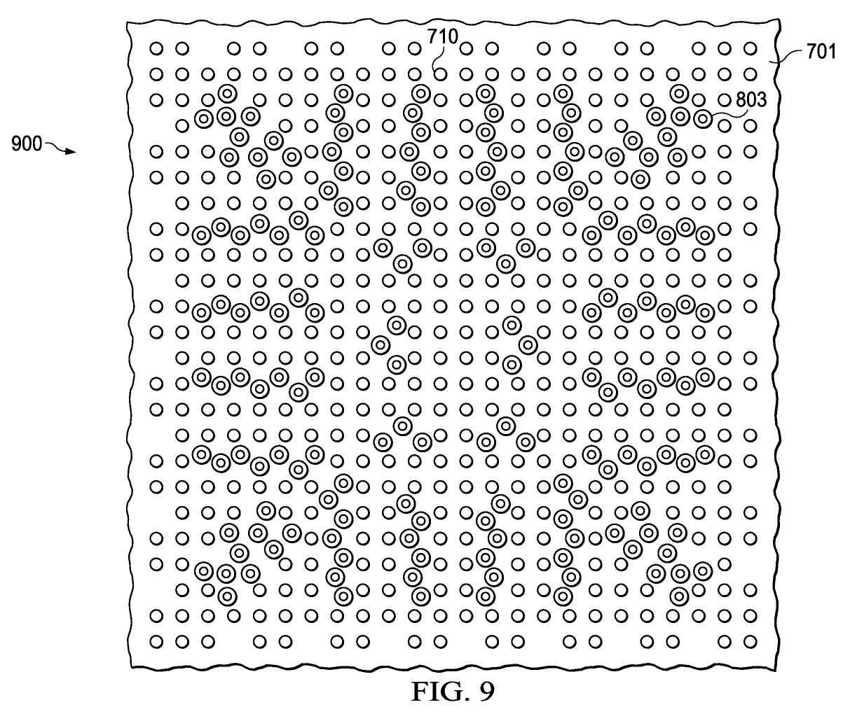

FIG. 9 depicts a view, generally designated 900, of the PCB surface 701 after the vias 803 are positioned in the via channels, the zones free of lands 710. FIG. 9 illustrates that by clustering the vias 803 into channels and separating the channels from the array of the lands 710, certain regions are freed up, where largely parallel sets of traces can now be formed at the internal metal layer. These traces have now enough space to use pitches and layout rules favorable for both high density (see below) and easy spacing without the need of providing additional PCB metal layers.

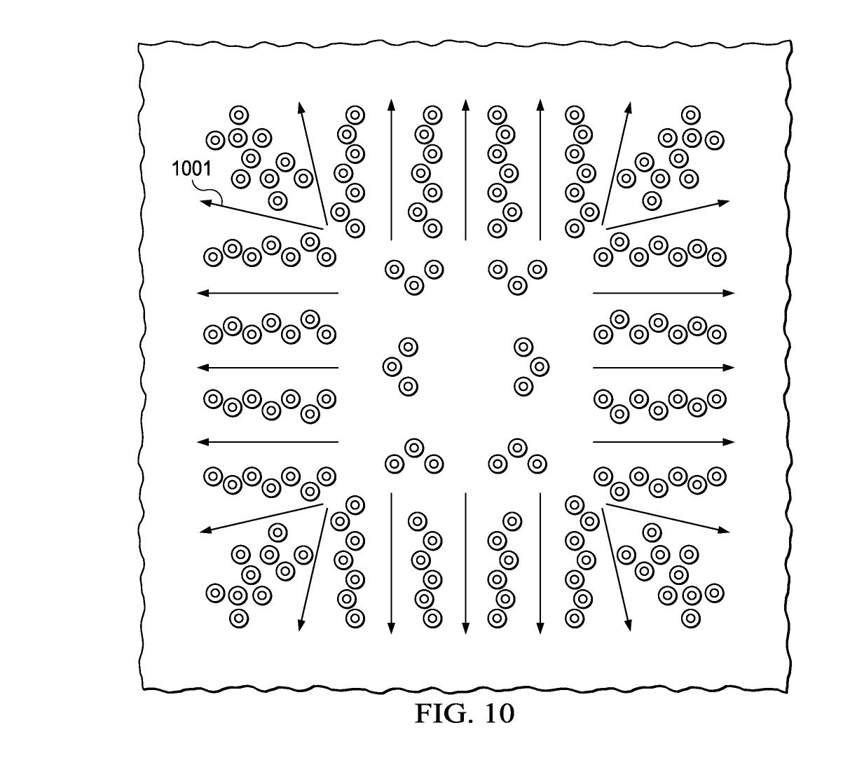

The regions freed up for the trace sets formed from the interior metal layer are highlighted in FIG. 10 by arrows 1001. As can be seen, the arrows indicate an unencumbered electrical flow through the trace sets from the array center, and thus the center of the device-to-be-assembled, to the external parts. For many electronic systems, the electrical flow includes foremost the system signals.

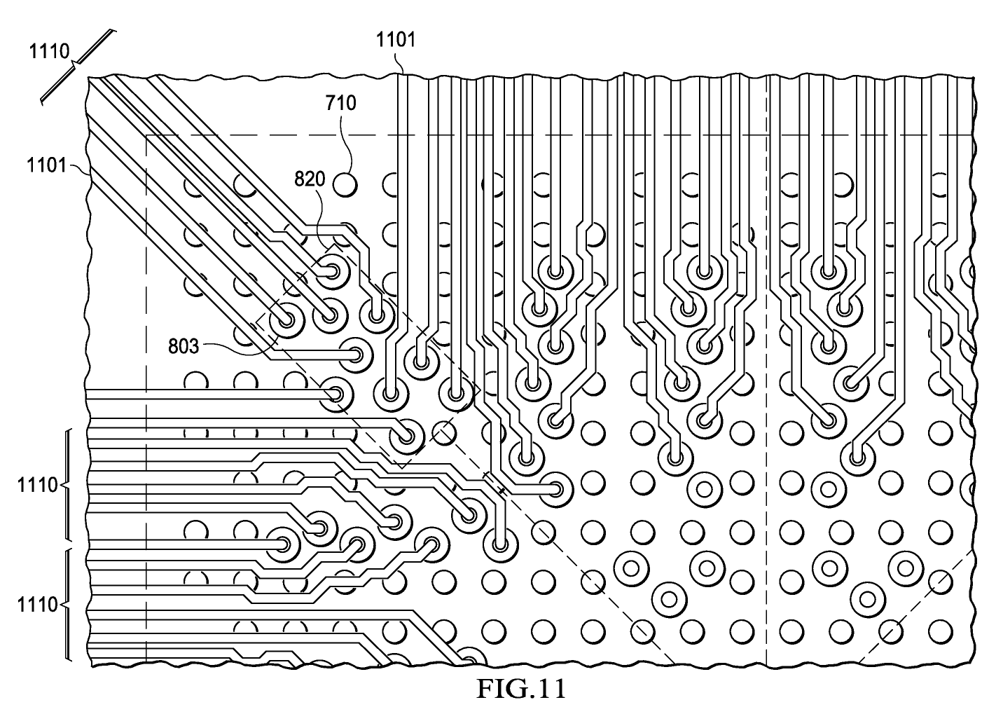

The technical advantage of forming sets of traces 1101 in the regions freed-up from blocking vias by arranging the vias 803 in via channels 820 is illustrated in FIG. 11. The Figure is an X-ray view of a PCB quadrant, wherein the traces 1101 of the interior metal layer are displayed together with the lands 710 on the PCB surface. As can be seen, each via 803 in a via channel 820 is connected to a trace 1101; the traces are grouped in sets 1110 so that each set positions the parallel portions of it in a region unencumbered by vias.

The grouping of the traces enables a considerably increased trace density of the internal PCB metal layer. In the example shown in FIG. 11, about 20 traces fit into 6 mm board length. The grouping allows the parallel portions of some adjacent traces to exhibit the minimum pitch permitted by the less expensive design rules (in the example quoted above, the trace width is 125 μm and trace spacing is 125 μm). The dense trace spacing avoids the need for additional internal PCB metal layers.

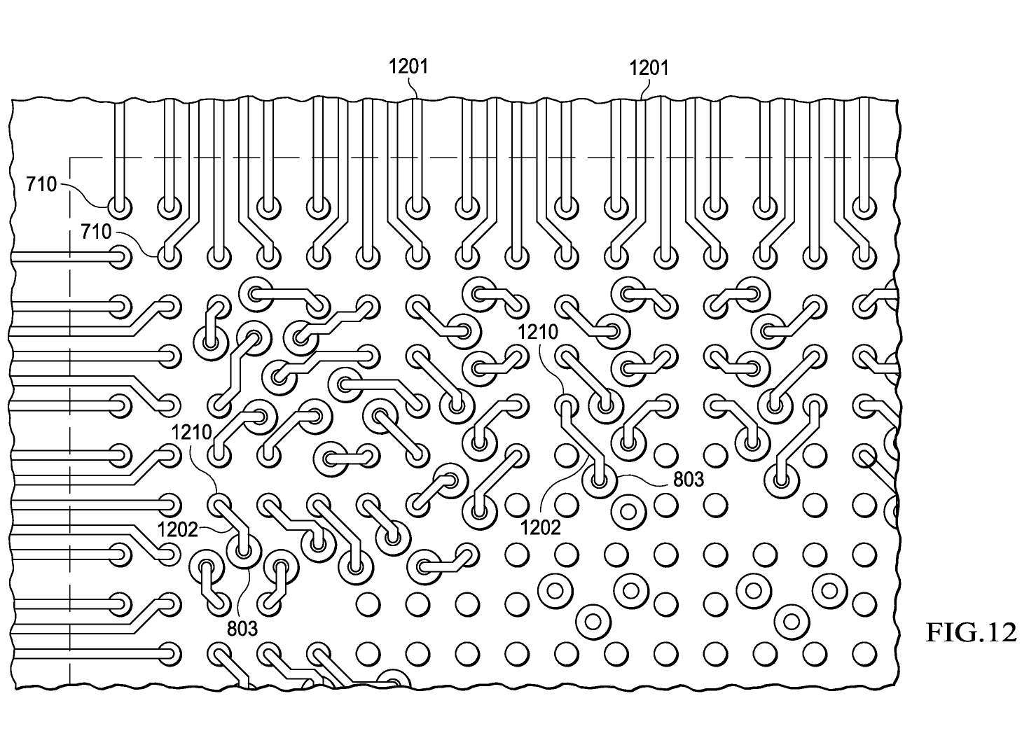

In addition to the traces 1101 of the internal metal layer discussed in FIG. 11, there are traces on the PCB surface, which are displayed in FIG. 12. The traces on the PCB surface include a set of traces designated 1201, which constitute substantially parallel traces for the lands 710 located at the two outermost lines and rows. Further included are traces designated 1202, which connect the lands 1210 starting from the third line and row from the periphery to the vias 803 in the via channels.

Also depicted in FIG. 12 an increased trace density with wide traces can be achieved for the first and second line and row from the periphery by depopulating every third land in the line and row nearest the periphery. Space is thus opened up for the traces from the lands in the adjacent line and row. This methodology provides, for the example discussed above, a trace density of about 20 traces per 7.2 mm PCB length at 125 μm trace width and 125 μm trace spacing.

Another embodiment of the invention is a method for fabricating an electronic system. In the first step of the method, a board made of insulator material is provided, wherein the board has a surface, a periphery, a metal layer on the surface and at least one internal metal layer.

Next, the metal layer on the board surface is patterned into lands so that the lands are located on sites of a regularly pitched array. The array sites may be aligned in lines and rows parallel to the rectangular board periphery, when a rectangular board is used. A first set of sites of lands connected to traces on the board surface; these traces have substantially parallel configuration at a trace pitch. A second set of sites of lands connected to traces formed on the at least one internal layer. The connection is enabled by conductive vias, which extend from the board surface through the insulator to the at least one metal layer.

The locations of the vias are selected so that the vias are clustered into elongated radial zones depopulated of lands. This clustering of vias frees up the space to position the traces formed of the internal layer into sets with substantially parallel configuration and minimum trace pitch.

In the next process step, a electronic device including a semiconductor chip is provided, which has metallization for contact pads. The contact pads are formed as a regularly pitched array, which includes elongated radial zones free of pads. The array and the pad-free zones match the land distribution and the land-free zones of the board surface.

The chip contact pads are electrically connected with the matching board lands. This connection can be made by a suitable technique including attachment by solder balls or gold bumps, and pressure contacts.

As stated above, the PCB has at least one internal metal layer. The traces formed of this metal layer, as well as the traces formed of the surface metal layer, preferably serve the signal connections of the device. For many devices, two additional PCB metal layers are needed for electrical power and ground connections. However, the methodology of the invention can be expanded to boards with more metal layers, while the number of needed layers is still reduced by grouping the conductive vias through the board in radially oriented zones freed up by depopulating contact lands, and thus placing the electrical traces in the newly created space.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to any type of semiconductor chip, discrete or integrated circuit, in a BGA-type package or any other multi-lead package. The material of the semiconductor chip may comprise silicon, silicon germanium, gallium arsenide, or any other semiconductor or compound material used in integrated circuit manufacturing.

As another example, the invention applies to boards or substrates with traces distributed on several levels, wherein a separation of the inter-level connections into radially oriented zones can be achieved by controlled depopulation of contacts and concentrating the traces into the freed-up spaces.

It is therefore intended that the appended claims encompass any such modifications or embodiment.

I claim:

1. An electronic system comprising:
a semiconductor ball grid array device having contact pads on sites of a two-dimensional array,
elongated radial zones of array sites free of contact pads; and
a printed circuit board having metallic lands matching the device pad distribution electrically connected to the pads and radial via zones matching the elongated radial zones.

2. The system of claim 1 further including metal bodies connecting the device contact pads and the board metallic lands.

3. An electronic device comprising:
a semiconductor chip; and
a substrate, on which the chip is assembled, having contact pads populating sites of a array and elongated zones of array sites free of contact pads surrounded by contact pads radially arranged on the substate.

4. The device of claim 3 further including metal bodies attached to the contact pads for external connection.

5. The device of claim 3 wherein the zones are beyond a center area of the substrate.

6. The device of claim 3 wherein the pads are aligned in rows and lines parallel to rectangular substrate sides.

7. A printed circuit board for assembling a packaged electronic device having contact pads in a two dimensional array and elongated radial zones free of pads surrounded by contact pads, comprising:
an insulating board having a surface and a periphery;
metallic lands on the surface on sites of a two dimensional array matching the contact pads of the device;
elongated radial zones matching the pad-free zones of the device;
at least one metal layer internal to the insulating material; and
conductive vias extending from the surface through the insulator to the at least one metal layer, the vias clustered in the zones.

8. The board of claim 7 wherein the array sites are aligned in rows and lines parallel to the board periphery, which is rectangular.

9. The printed circuit board of claim 7 further including metal traces comprising:
traces on the board surface including:
a first set of substantially parallel traces connected to the lands located at the outermost row and an adjacent row of the array; and
traces connecting the lands on a third row of the array remote from the periphery to the vias in the zones; and
traces formed on the at least one metal layer contacting the vias including a second set of substantially parallel traces.

10. The board of claim 9 wherein the array has a pitch of about 0.65 mm and the trace has a width of about 125 μm.

11. The board of claim 7 further including one additional internal metal layer for traces, the substantial parallel traces on the two internal layers connecting signal input/outputs of the device.

12. The board of claim 7 further including one or more additional internal metal layers for traces connecting electrical power and ground potential of the device.

13. A method for fabricating an electronic system, comprising the steps of:
forming metallic lands on sites of a two dimensional array on a surface of an insulating board,
connecting a first set of lands to substantially parallel metal traces on the surface of the board; and
connecting a second set of lands to substantially parallel traces on at least one internal metal layer by conductive vias clustered into elongated radial zones free of pads,
providing a semiconductor package having metallic contact pads matching the lands; and
connecting the package contact pads to the matching lands.

14. The method of claim 13 wherein the package has a rectangular periphery.

15. The method of claim 14 wherein the array sites are aligned in rows and lines parallel to the rectangular board periphery.
